(19) United States
(12) Patent Application Publication
(10) Pub. No.: US 2024/0222208 A1
(43) Pub. Date: Jul. 4, 2024

(54) Power electronic module, power electronic module block, printed circuit board with power electronic module or printed circuit board component,and method for producing a power electronic module

(71) Applicant: Schweizer Electronic AG, Schramberg (DE)

(72) Inventor: Thomas GOTTWALD, Dunningen (DE)

(21) Appl. No.: 18/541,107

(22) Filed: Dec. 15, 2023

(30) Foreign Application Priority Data
Dec. 30, 2022 (DE) 10 2022 135 026.6

(51) Int. Cl. H01L 23/13; H01L 21/48; H01L 23/367; H01L 23/498; H05K 1/18; H05K 7/20

(52) U.S. Cl. CPC H01L 23/13; H01L 21/4853; H01L 21/4857; H01L 21/486; H01L 23/367; H01L 23/49811; H05K 1/186; H05K 7/20218; H01L 24/32

(57) ABSTRACT

A power electronic module (10) for integration into a printed circuit board (50), comprising a carrier substrate (12) and a power electronic component (16) fitted into a recess (14) provided for this purpose in the carrier substrate (12), wherein the carrier substrate (12) is formed as a heat sink or heat dissipation body composed of one or more materials of high thermal conductivity at least in a region below the power electronic component (16).

### TECHNICAL FIELD

The invention relates to a power electronic module and to a power electronic module block and also to a printed circuit board with a power electronic module or a power electronic module block.

### DESCRIPTION OF THE PRIOR ART

EP 2 524 394 B1 discloses an electronic device that is provided for integration into a printed circuit board and comprises an electrically conductive core layer with further electrically conductive layers applied on both sides, wherein an electronic component is arranged in a cutout of the further electrically conductive layer. For the purpose of integration into a printed circuit board, the electronic device is inserted into a cutout provided therefor in the printed circuit board and is pressed together with the latter in such a way that, after pressing, the surface of the printed circuit board terminates flush with the surface of the device as a common outer layer of the printed circuit board and of the device, a copper layer serving as an interface to a heat sink is subsequently applied.

DE 10 2018 207 955 A1 discloses a power electronic metal-ceramic module comprising a metal-ceramic substrate composed of a ceramic carrier with a metal upper layer and a metal lower layer. A frame is provided on or in the metal upper layer, said frame receiving an electronic component.

DE 10 2020 132 808 A1 discloses a printed circuit board module comprising a printed circuit board and a heat sink and also, provided between the printed circuit board and the heat sink, a planar heat-conducting element, which comprises a ceramic carrier coated with a phase change material. The printed circuit board has a printed circuit board layer structure with a leadframe arranged in a cutout, with an electronic component arranged in a recess formed in said leadframe.

### SUMMARY OF THE INVENTION

Taking this as a departure point, the invention proposes a power electronic module having the features of claim 1 and a power electronic module block having the features of claim 12. A printed circuit board having the features of claim 13 and a method for producing a power electronic module having the features of claim 18 are furthermore proposed.

According to the invention, the carrier substrate is formed as a heat sink or heat dissipation body composed of one or more materials of high thermal conductivity at least in a region below the power electronic component, which allows direct use of the carrier substrate as a heat-dissipating element. In particular, this enables cooling fluid to flow directly around the carrier substrate in the manner according to the invention. The insight of the invention is based on minimizing the thermal resistance of the carrier substrate in order to achieve particularly efficient heat dissipation. The thermal resistance in the overall construction of the carrier substrate should not exceed 1 K/W per cell (i.e. per assigned component). Values sought are from 0.1 K/W to 0.4 K/W per cell without taking account of a cooling-fluid-guiding structure. If a plurality of cells are connected in parallel, the thermal resistances behave like ohmic resistances (1/Rₜₒₜ=1/R₁+1/R₂. . . +1/Rₙ).

In the present case, the term power electronic module block should be understood to mean a semifinished product which comprises a power electronic component and which is provided for integration into a printed circuit board. According to the invention, it is formed by suitable encapsulation of a power electronic module according to the present invention.

Further advantages and configurations of the invention are evident from the dependent claims, the description and the accompanying drawing.

A numbered list of aspects of the invention is presented below:
1. A power electronic module for integration into a printed circuit board, comprising a carrier substrate and a power electronic component fitted into a recess provided therefor in the carrier substrate, wherein the carrier substrate is formed as a heat sink or heat dissipation body composed of one or more materials of high thermal conductivity at least in a region below the power electronic component.
2. The power electronic module according to aspect 1, wherein a component-remote section of the carrier substrate is configured for contact with cooling fluid.
3. The power electronic module according to aspect 2, wherein the component-remote section of the carrier substrate is configured for direct contact with cooling fluid.
4. The power electronic module according to aspect 3, wherein the component-remote section of the carrier substrate has a coating compatible with cooling fluid.
5. The power electronic module according to any of aspects 1 to 4, wherein a component-remote section of the carrier substrate has surface-enlarging or heat-dissipating structures and/or cooling-fluid-guiding structures.
6. The power electronic module according to any of aspects 1 to 4, wherein a component-remote section of the carrier substrate is assigned surface-enlarging or heat-dissipating structures and/or cooling-fluid-guiding structures, e.g. as a separately formed cooling structure body, which is fitted to an outer surface of the metal lower layer in particular by means of joining, and the basic area of which can be e.g. greater than the basic area of the carrier substrate or of the metal lower layer.
7. The power electronic module according to aspect 5 or 6, wherein surface-enlarging or heat-dissipating structures and/or cooling-fluid-guiding structures are in particular channels, cooling fins, cooling pins, studs and/or contact-connections or the like.
8. The power electronic module according to any of aspects 1 to 7, wherein the carrier substrate comprises a multilayer structure with an insulating inner layer, a metal upper layer assigned to the power electronic component, and a component-remote metal lower layer.
9. The power electronic module according to aspect 8, wherein the multilayer structure is a metal-ceramic substrate with a ceramic carrier as insulating inner layer.
10. The power electronic module according to aspect 8 or 9, which has a connection element extending outside the multilayer structure substantially perpendicularly to the layers of the multilayer structure for the purpose of electrical connection of the power electronic component.
11. The power electronic module according to aspect 10, wherein the connection element extends over a height of the carrier substrate as far as the metal lower layer.
12. The power electronic module according to aspect 11, wherein the connection element terminates substantially flush with an outer surface of the metal lower layer.
13. A power electronic module for integration into a printed circuit board, comprising a carrier substrate formed as a heat sink or heat dissipation body composed of one or more materials of high thermal conductivity in particular at least in a region below the power electronic component, and a power electronic component introduced into a recess provided for this purpose in the carrier substrate, wherein the carrier substrate comprises a multilayer structure with an insulating inner layer, a metal upper layer assigned to the power electronic component, and a component-remote metal lower layer, wherein the module has a connection element extending outside the multilayer structure substantially perpendicularly to the layers of the multilayer structure for the purpose of electrical connection of the power electronic component, the connection element extending over a height of the carrier substrate as far as the metal lower layer and terminates substantially flush with an outer surface of the metal lower layer.
14. The power electronic module according to any of aspects 8 to 13, wherein a frame for receiving the power electronic component is provided on or in the metal upper layer, which frame consists of electrically conductive material and, for the purpose of forming an electrical connection element for the power electronic component, comprises a section projecting beyond the carrier substrate.
15. The power electronic module according to aspect 14, wherein a thickness of the frame corresponds to a thickness or height of the component.
16. The power electronic module according to any of aspects 1 to 15, wherein a thickness of the recess corresponds to a thickness or height of the component.
17. The power electronic module according to any of aspects 14 to 17, wherein the section projecting beyond the carrier substrate is designed to be bendable.
18. The power electronic module according to aspect 17, wherein the section projecting beyond the carrier substrate is bent in such a manner that it extends over a height of the carrier substrate as far as the metal lower layer.
19. The power electronic module according to aspect 18, wherein the section projecting beyond the carrier substrate is bent in such a manner that it terminates substantially flush with an outer surface of the metal lower layer.
20. The power electronic module according to aspect 18 or 19, wherein the bent section has substantially an S-shape or a double S-shape in cross section.
21. The power electronic module according to any of aspects 14 to 16, wherein additionally the metal upper layer and the ceramic carrier together with the frame project beyond the carrier substrate and a conduction section extending through the layer of the ceramic carrier is provided for the purpose of forming the electrical connection element.
22. The power electronic module according to aspect 21, wherein the conduction section is formed by means of at least one through contact through the ceramic carrier.
23. A power electronic module block for integration into a printed circuit board, the power electronic module block being formed from a power electronic module according to any one of aspects 13 to 22, wherein the module is encapsulated by means of injection molding or transfer molding with a mold compound to form a monolithic block in such a way that an upper outer surface of the carrier substrate and an outer surface of the metal lower layer are suitably exposed for contact-connection.
24. The module block according to aspect 23, wherein the mold compound is selected from the group of formaldehydes, in particular phenoplasts or melamine resins, or reaction resins, in particular polyesters or in particular epoxy resins.
25. The module block according to aspect 23 or 24, which is produced by means of foil or film assisted transfer molding.
26. A printed circuit board comprising a printed circuit board layer structure and a power electronic module according to any of aspects 1 to 22 that is inserted into the printed circuit board layer structure and pressed together with the latter.
27. The printed circuit board according to aspect 26, comprising a cooling fluid flow body arranged at an outer surface of the printed circuit board in a manner assigned to a component-remote section of the carrier substrate.
28. The printed circuit board according to aspect 27, wherein a component-remote section of the carrier substrate is exposed, in particular by deep milling, in order to allow cooling fluid to be applied.
29. The printed circuit board according to aspect 28, wherein the cooling fluid flow body has a cooling fluid guide structure designed to feed cooling fluid to the exposed component-remote section for, in particular direct, flow around.
30. The printed circuit board according to aspect 28 or 29, wherein the cooling fluid flow body has cooling channels at a surface facing the exposed component-remote section.
31. The printed circuit board according to any one of aspects 26 to 30, comprising a power electronic module according to any one of aspects 10 to 21 that is inserted into the printed circuit board layer structure and pressed together with the latter, wherein the connection element is electrically connected, e.g. by joining or by means of inner layer connections, to a conductive layer of the printed circuit board layer structure that terminates substantially flush with the metal lower layer.
32. A printed circuit board comprising a printed circuit board layer structure and a module block according to any one of aspects 23 to 25 that is inserted into the printed circuit board layer structure and pressed together with the latter.
33. The printed circuit board according to aspect 32, wherein the connection element of the printed circuit board component is electrically connected, e.g. by joining or by means of inner layer connections, to a conductive layer of the printed circuit board layer structure that terminates substantially flush with the metal lower layer.
34. The printed circuit board according to aspect 32 or 33, comprising a cooling fluid flow body arranged at an outer surface of the printed circuit board in a manner assigned to a component-remote section of the carrier substrate.
35. The printed circuit board according to aspect 34, wherein a component-remote section of the carrier substrate is exposed, in particular by deep milling, in order to allow cooling fluid to be applied.
36. The printed circuit board according to aspect 35, wherein the cooling fluid flow body has a cooling fluid guide structure designed to feed cooling fluid to the exposed component-remote section for, in particular direct, flow around.
37. The printed circuit board according to aspect 35 or 36, wherein the cooling fluid flow body has cooling channels at a surface facing the exposed component-remote section.
38. A method for producing a power electronic module, in particular according to aspect 21 or 22, comprising the following steps:
   providing an initial carrier substrate comprising an insulating inner layer, a metal lower layer formed thereunder, and a metal upper layer formed thereon,
   forming one or more holes through the metal lower layer and the insulating inner layer,
   filling the holes with electrically conductive material for the purpose of forming through contacts,
   etching the metal lower layer for the purpose of forming a potential-isolated terminal layer.
39. The method according to aspect 38, further comprising the step of chemical metal deposition in the holes before the filling step.
40. The method according to aspect 38 of 39, further comprising the step of applying further metal to the metal upper layer and/or the metal lower layer.
41. The method according to aspect 40, wherein before the step of applying further metal, a defined region of the metal upper layer is covered with photoresist material in order to form a recess for receiving a power electronic component by way of applying metal, followed by the step of removing the photoresist material.
42. The method according to any one of aspects 38 to 40, further comprising the step of applying a frame to the metal upper layer with a cutout for receiving a power electronic component, e.g. by means of joining, in particular sintering.
43. The method according to aspect 41 or 42, further comprising the step of inserting a power electronic component into the recess in the metal upper layer or the cutout in the frame.
44. The method according to aspect 43, further comprising the step of encapsulating the power electronic module by means of injection molding/transfer molding to form a monolithic block for forming a power electronic module block suitable for integration into a printed circuit board.

It goes without saying that the features mentioned above and those yet to be explained below can be used not only in the combination indicated in each case, but also in other combinations, or by themselves, without departing from the scope of the present invention.

The invention is illustrated on the basis of exemplary embodiments highly schematically and in a manner not true to scale in the drawing and is described in detail below with reference to the drawing.

### BRIEF DESCRIPTION OF THE DRAWING

FIG. 1 shows, in a lateral sectional view, a detail from a printed circuit board with a power electronic module according to the invention that is pressed and con-tact-connected in the printed circuit board, in accordance with a first embodiment.

FIG. 2 shows the lateral sectional view of FIG. 1 with an exposed underside of the carrier substrate.

FIG. 3 shows the lateral sectional view of FIG. 2 with a cooling fluid flow body fitted to the printed circuit board.

FIG. 4 shows the lateral sectional view of FIG. 3 with a first sealing variant.

FIG. 5 shows the lateral sectional view of FIG. 3 with a second sealing variant.

FIG. 6 shows the lateral sectional view of FIG. 3 with cooling structures formed at the carrier substrate.

FIG. 7 shows the lateral sectional view of FIG. 3 with a power electronic module according to the invention that is pressed and contact-connected in the printed circuit board, in accordance with a second embodiment.

FIG. 8 shows the lateral sectional view of FIG. 7 with cooling structures formed at the carrier substrate.

FIG. 9 shows the lateral sectional view of FIG. 7 with a further variant of cooling structures formed at the carrier substrate.

FIG. 10 shows the lateral sectional view of FIG. 7 with yet another variant of cooling structures formed at the carrier substrate.

FIG. 11 shows, in a lateral sectional view, one embodiment of a power electronic module according to the invention.

FIG. 12 shows the depiction of FIG. 11 in top view.

FIG. 13 shows the depiction of FIG. 12 in one configuration variant.

FIG. 14 shows the depiction of FIG. 11 with a bent connection element.

FIG. 15 shows, in a lateral sectional view, one embodiment variant of the power electronic module from FIG. 14.

FIG. 16 shows, in a lateral sectional view, a detail from a printed circuit board with a power electronic module according to the invention that is pressed and con-tact-connected in the printed circuit board, in accordance with the illustration from FIG. 14.

FIG. 17 shows the depiction of FIG. 16 with an alternative terminal design of the connection element.

FIG. 18 shows, in a lateral sectional view, a detail from a printed circuit board with a power electronic module according to the invention that is pressed, contact-connected and partly exposed in the printed circuit board, in accordance with the depiction of FIG. 15.

FIG. 19 shows one configuration variant of the depiction of FIG. 16.

FIG. 20 shows one configuration variant of the depiction of FIG. 18.

FIG. 21 shows the power electronic module according to the invention of FIG. 14 as an encapsulated module (module block).

FIG. 22 shows, analogously to the view in FIG. 21, the power electronic module according to the invention from FIG. 14 as an encapsulated double module.

FIG. 23 shows one configuration variant of the depiction of FIG. 22.

FIGS. 24 to 29 show lateral sectional views of sequences during the manufacture of a power electronic module according to the invention with a construction similar to that of the embodiment variant illustrated in FIG. 15.

### DETAILED DESCRIPTION

Identical and similar features illustrated in the individual figures are designated by identical reference signs.

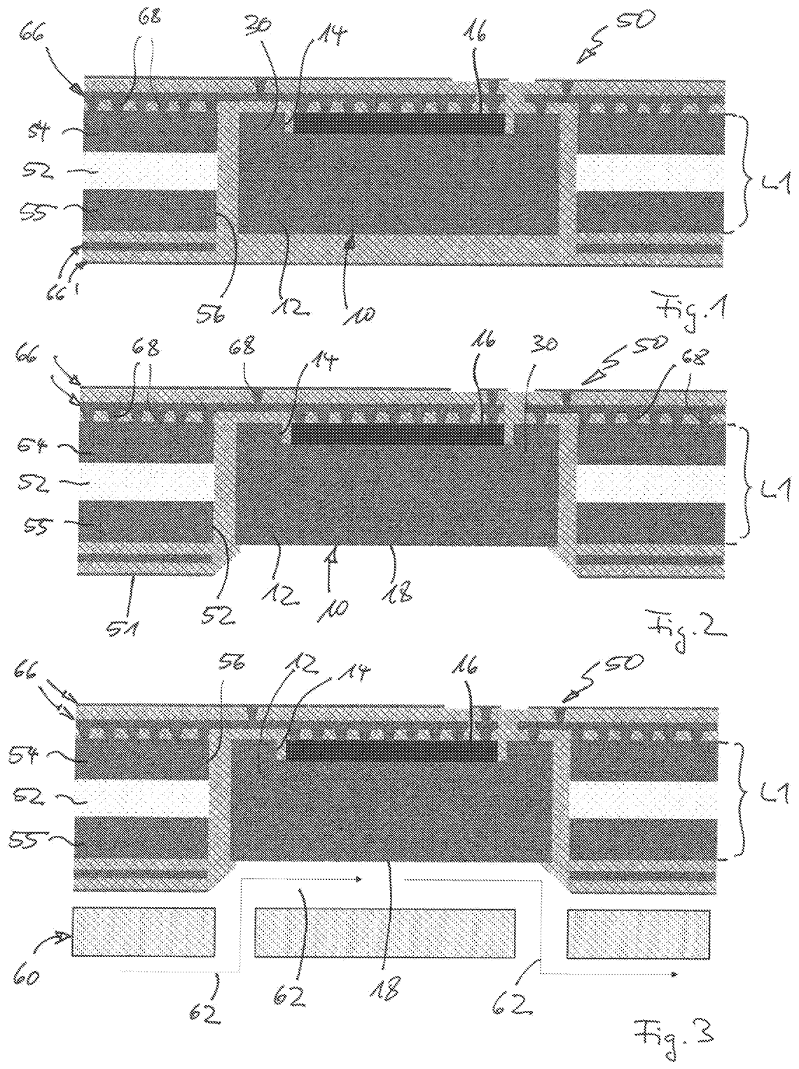

FIG. 1 shows, in a lateral sectional view, a printed circuit board 50 comprising a printed circuit board layer structure L1 known per se. The printed circuit board in FIG. 1 shows an exemplary layer structure such as can be used in association with the present invention. However, the invention can also be used for all possible types and designs of printed circuit boards. In particular, the invention is suitable for the use of power converters with printed circuit boards with high-current applications owing to the efficient heat dissipation. Possible printed circuit board constructions are described e.g. in EP 2 524 394 B1 or EP 2 973 687 B1.

The printed circuit board layer structure L1 of the printed circuit board 50 in FIG. 1 comprises by way of example, as illustrated, a nonconductive core layer 52 with copper layers 54, 55 applied on both sides. A power electronic module 10 according to the invention comprising a power electronic component (chip, MOSFET or the like) 16 arranged in a recess 14 formed in said module is embedded in a recess 56. In the embedded state, an upper copper layer 54 terminates toward the top substantially flush with the power electronic component 16 and the top side of the substrate and a lower copper layer 55 terminates toward the bottom substantially flush with a component-remote underside of the power electronic module 10.

Gaps and interspaces are filled, in a manner known per se, by prepreg material 58 that is liquefied and then solidified again during the lamination process. On a top side of the layer structure L1, conductor track layers 66 are provided, the conductor tracks of which are contact-connected by means of vias (μ-vias) 68 in a manner known per se. For the purpose of obtaining a symmetrical construction, corresponding conductor tracks 66′ without con-tact-connection are formed on the underside of the layer structure L1. The conductor tracks 66, 66′ with intervening nonconductive layers and the contact-connections or through contacts 68 can be formed, by means of techniques known per se, after the introduction and pressing of the power electronic module 10 into the printed circuit board layer structure L1.

FIG. 2 shows the illustration from FIG. 1 with an exposed underside of the power electronic module 10, such that a component-remote section 18 of the carrier substrate 12 is exposed. The exposing can be effected e.g. by means of deep milling or some other technique known to a person skilled in the art.

FIG. 3 shows the illustration from FIG. 2 with a cooling fluid flow body 60 placed at an underside 51 of the printed circuit board 50. The cooling fluid flow body 60 is assigned to the exposed component-remote section 18 of the carrier substrate 12. The cooling fluid flow body 60 has a cooling fluid guide structure 62 configured in such a way that together with the exposed component-remote section 18 it forms a throughflow channel 64. Cooling fluid guided through the throughflow channel 64 thus flows around the exposed component-remote section 18 of the carrier substrate 12 and ensures efficient heat dissipation. According to the invention, there may thus be direct contact between the carrier substrate functioning as a heat sink and the cooling fluid supplied.

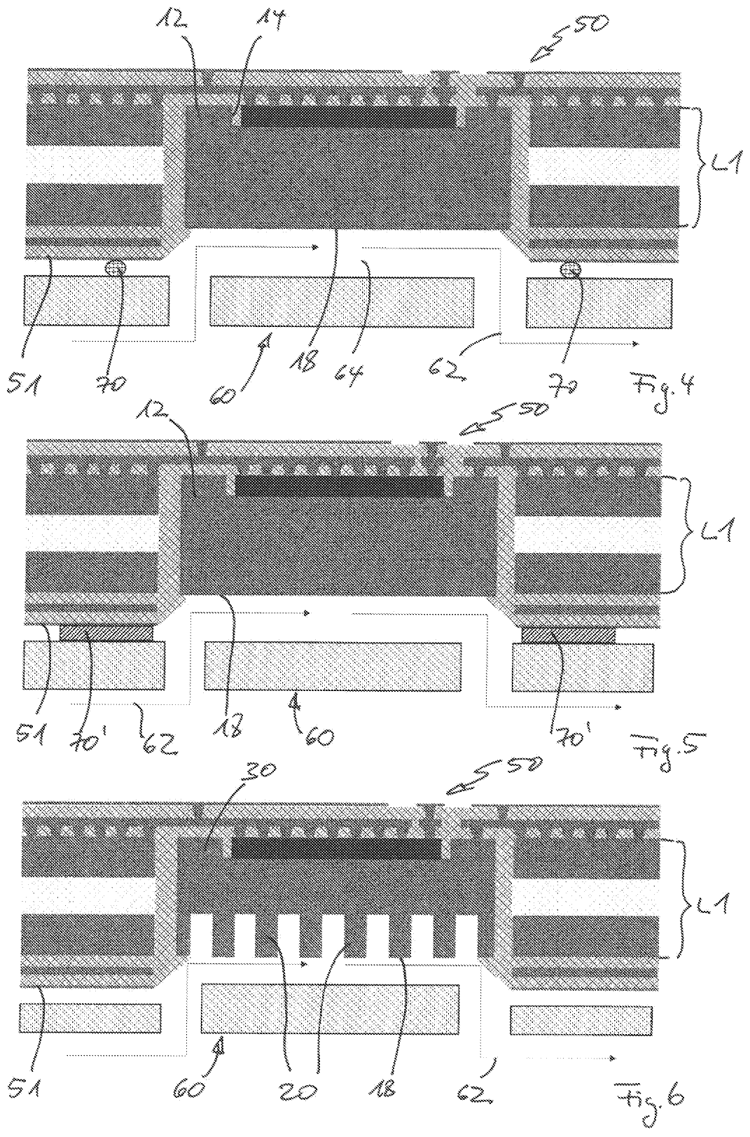

The illustration in FIG. 3 (and also in the further FIGS. 4 to 8) merely shows a schematic detail of the cooling fluid flow body 60 with the features that are relevant to use with the present invention.

Within the meaning of the invention, the cooling fluid flow body 60 is a body which is connectable to the printed circuit board in a suitable manner and which is designed to feed cooling fluid to the exposed component-remote section 18 for, in particular direct, flow around. This can involve—as indicated schematically in the figures—a channel structure which, at a location assigned to the power electronic module 10, as per the depicted arrows 62, guides cooling fluid from the interior of the cooling fluid flow body 60 outward for flow-around contact with the power electronic module 10 and, after flow-around has taken place, guides said cooling fluid back into the interior of the cooling fluid flow body 60 again. For this purpose, the cooling fluid flow body 60 can have suitable cooling fluid guiding channels (cooling channels) on its flow outer surface facing the power electronic module 10, said channels ensuring uniform flow against the carrier substrate.

The cooling fluid flow body 60 can be sealed vis-à-vis the printed circuit board 50 by means of a suitable sealing element such as an O-ring 70 (cf. FIG. 4) or a surface seal 70′ or adhesive seal (cf. FIG. 5). In the case where an O-ring is used, corresponding grooves for receiving the O-ring can be provided (not illustrated) in the underside 51 of the printed circuit board 50 and/or in the cooling fluid flow body 60.

The cooling can be configured as liquid cooling (liquid cooling fluid) or else as air or gas cooling (gaseous cooling fluid, in particular air). By way of example, water, oils, alcohols or the like or optionally also mixtures thereof can be provided as liquid cooling fluid. If the cooling fluid is air, the cooling fluid flow body is formed as a fan or blower.

According to the invention, the carrier substrate 12 of the power electronic module 10 can be formed with surface-enlarging or heat-dissipating structures and/or cooling-fluid-guiding structures at its component-remote section 18. FIG. 6 shows by way of example a configuration of a component-remote section 18 with cooling fins 20, around which the cooling fluid guided in by the cooling fluid flow body 60 flows. The cooling fins 20 can be formed e.g. by milling in the component-remote section 18. Other possible structures comprise e.g. cooling pins or cooling studs. Alternatively, the surface-enlarging or heat-dissipating structures can also be embodied as channels formed complementarily to the cooling channels of the cooling fluid flow body 60.

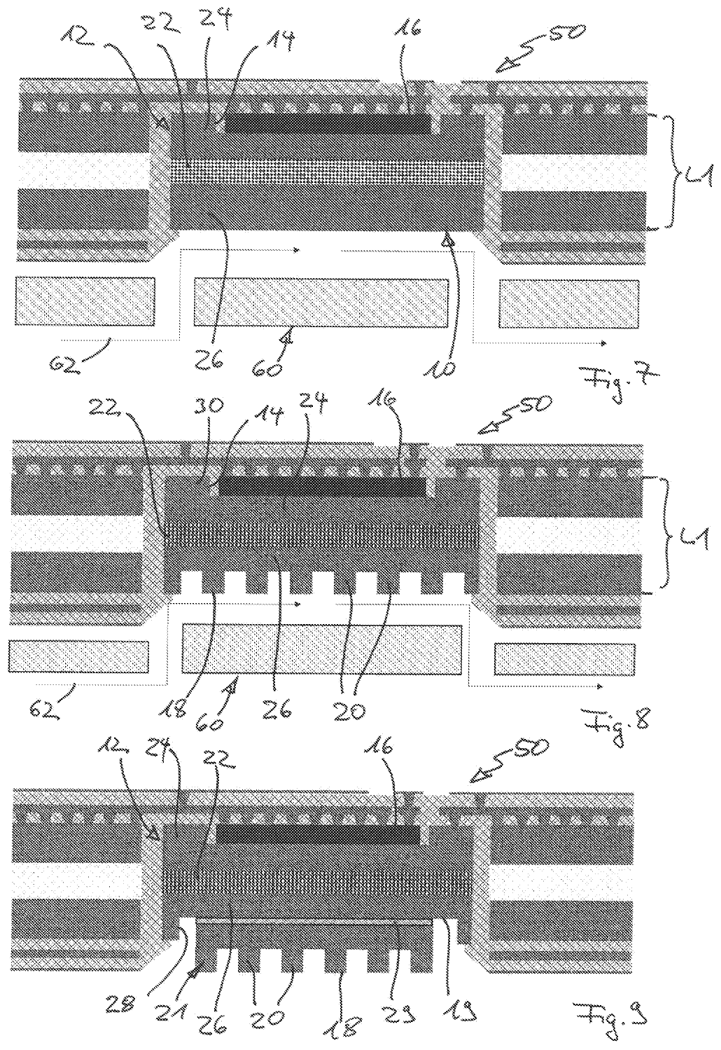

In the illustrations in FIGS. 1 to 6, the carrier substrate 12 is formed as e.g. a monolithic unit composed of conductive material, such as copper, in particular. If the power electronic component 16 is e.g. a field effect transistor (MOSFET or the like), this has the consequence that the drain potential would be present at the cooling fluid and the cooling fluid flow body by way of the conductive material of the carrier substrate 12. In order to avoid this, the carrier substrate 12 can alternatively be formed with an inner insulation layer, e.g. with a ceramic layer. One variant of this type is illustrated in FIGS. 7 to 10, in which the carrier substrate is formed as a metal-ceramic substrate 12.

FIG. 7 shows an illustration which is analogous to FIG. 3 and in which the carrier substrate 12 comprises a ceramic carrier 22 with a metal upper layer 24 and a metal lower layer 26. The metal layers 24, 26 are e.g. and in particular copper layers. Metal-ceramic substrates of this type are available e.g. as so-called DCB substrates (DCB: Direct Copper Bond). By way of example, Al₂O₃, AlN (aluminum nitride) or other compounds familiar to a person skilled in the art are appropriate as ceramic material. Layer thicknesses of the ceramic typically amount to approximately 100 to approximately 1,000 μm, preferably to approximately 150 to approximately 400 μm, and the thicknesses of the metal layers are typically likewise between approximately 50 and approximately 1,000 μm, preferably between approximately 200 and approximately 600 μm. The layer thicknesses can be chosen e.g. in a ratio of 2:1:2 (from top to bottom). A configuration of this type affords electrical insulation from the cooling fluid circuit.

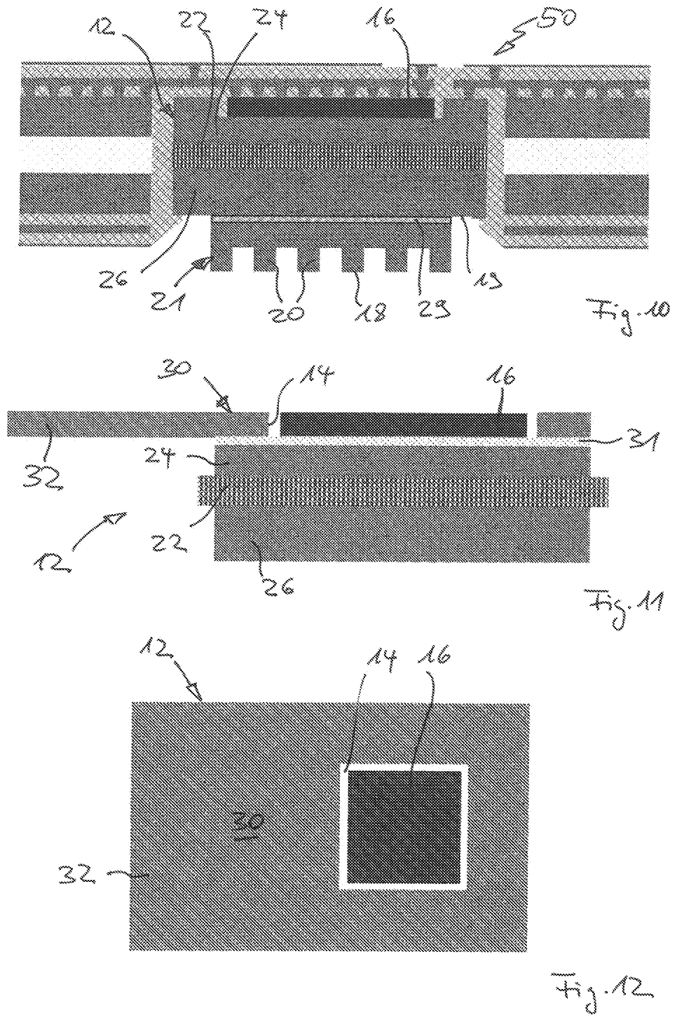

FIG. 8 shows an illustration analogous to FIG. 6 with cooling fins 20 formed in the component-remote section 18 of the metal-ceramic substrate 12. FIGS. 9 and 10 show variants in which cooling fins 20 are not introduced directly into the metal lower layer 26, rather provision is made of a separately formed cooling structure body 21 assigned to the carrier substrate. The cooling structure body 21 can be applied to the metal lower layer 26—more precisely the component-remote outer surface 19 thereof—in particular by joining, such as sintering or the like (also cf. paragraphs hereinafter).

In the exemplary embodiments in FIGS. 9 and 10, the cooling structure body is a cooling fin body 21 connected to the carrier substrate 12, specifically the (exposed) metal lower layer 26 of the carrier substrate 12. For this purpose, as in the example in FIG. 9, for example, a cutout 28 can be introduced into the metal lower layer 26 (by milling or the like), the cooling fin body 21 being introduced into said cutout, e.g. by means of sintering, soldering or the like (cf. sintering layer 29).

In the exemplary embodiment in FIG. 10, the cooling structure body is applied directly to the exposed metal lower layer 26 (once again by sintering, soldering or the like), without a cutout previously having been introduced as in the exemplary embodiment in FIG. 9. Of course, the cooling structure body can comprise cooling channels (not shown in detail) towards the component-remote section 18 of the carrier substrate 12 for the flow of cooling fluid, so that there is direct cooling fluid con-tact with the carrier substrate.

In any case, in the course of exposing the component-remote section 18, on account of required tolerances, it is possible for the metal surface of the metal lower layer 26 to be removed over part of the area or over the whole area. This removing can also extend beyond the area of the metal lower layer in the X-direction and/or Y-direction, in order to facilitate mounting. The cooling structure body or cooling fin body 21 can be applied e.g. by way of surface mounting (SMT: Surface-mount technology). For better heat spreading, a basic area of the cooling structure body can be chosen to be greater than that of the component-remote outer surface 19 of the metal lower layer 26. If the carrier substrate has a basic area of 11 mm×11 mm, for example, the basic area of the cooling structure body could be chosen to be 15 mm×15 mm, for example.

In the exemplary embodiments in FIGS. 9 and 10, analogously to the description given above, a cooling fluid flow body 60 (not illustrated here) can be applied. In the case of the design of the cooling fluid flow body, the projection of the applied cooling fin body 21 should be taken into consideration compared with the recessed cooling fin structure illustrated e.g. in FIG. 8.

If a plurality of power electronic modules 12 are integrated into a printed circuit board 50, the metal surface of the metal lower layer 26 of a respective module can in this case be exposed individually for each of the modules 12 present and each substrate can be provided with a dedicated cooling dissipation structure as disclosed. However, it is also possible for the surfaces to be exposed group-wise for a plurality of adjacent modules. A plurality of modules can then be connected to a common cooling dissipation structure as disclosed.

The cooling structure body or cooling fin body can be produced e.g. by means of extrusion. It goes without saying that the configuration of the cooling fin body is not restricted to cooling fins, rather said cooling fin body can alternatively have all other possible surface-enlarging or heat-dissipating structures known to a person skilled in the art. The described variant with a separate cooling structure body can, of course, also be realized in association with the carrier substrate used in the exemplary embodiments in FIGS. 1 to 5.

As described, the invention thus encompasses the two variants according to which the power electronic module can be either electrically non-insulating (hence composed of metal, in particular copper) or electrically insulating (with an inner insulating layer such as ceramic, in particular). If an insulating layer is used, care should be taken to ensure, as claimed, that it has a sufficiently high thermal conductivity. On the one hand, it is possible to use ceramics, for example, which typically have a thermal conductivity in the range of 18 to 190 W/mK. On the other hand, it is also possible to use organic materials for the purpose of electrical insulation, which regularly have a lower thermal conductivity, typically in the range of 0.2 to 10 W/mK. The decisive factor when choosing the thickness of the insulating layer will be a balance between the electrical insulation properties and the thermal conductivity, as evident to a person skilled in the art.

In both cases, the component-remote section of the carrier substrate consists of metal/copper. In order to prevent or reduce corrosion of the metal that comes into contact with the cooling fluid, and thus contamination of the cooling fluid and corrosion in the cooling system, the area of the carrier substrate that comes into contact with cooling fluid can have a suitable protective coating (not illustrated in the figures), i.e. a coating compatible with cooling fluid. Such a coating is distinguished by a high degree of pore tightness. One possible example is a plating with nickel, e.g. with a layer thickness of approximately 5 to 50 μm. The layer should be as thin as possible in order that the thermal conductivity is not adversely affected un-necessarily. If oil is used as cooling fluid, a coating may possibly be dispensed with.

If an insulating inner layer is used in the carrier substrate, as described above, then the drain potential is no longer present at the component-remote section of the carrier substrate, which in turn has the consequence that it is no longer possible straightforwardly to realize a drain contacting in a lower, i.e. component-remote, level of the layer structure of the printed circuit board. In order nevertheless to make this possible, the embodiments illustrated in FIGS. 11 to 23 are furthermore proposed according to the invention.

According to the invention, in the cases of a carrier substrate 12 with a multilayer structure with an insulating inner layer 22, a connection element 34 is provided extending outside the multilayer structure substantially perpendicularly to the layers of the multilayer structure for the purpose of electrical connection of the power electronic component 16 or the drain contact thereof, as is illustrated in FIGS. 11 to 23.

The connection element 34 can extend over a height of the carrier substrate 12 as far as the metal lower layer 26 and in particular terminate flush (with respect to said metal lower layer's underside or outer surface 27 of the component-remote section 18) with said metal lower layer.

In accordance with a first embodiment, for this purpose, the invention provides for a frame 30 for receiving the power electronic component 16 to be provided on or in the metal upper layer 24. This frame 30 is also provided in the exemplary embodiments in FIGS. 1 to 10, where it is formed integrally with the metal of the carrier substrate or the metal upper layer 24. In the exemplary embodiments in FIGS. 11 to 23 that are now to be discussed, it is appropriate to form this frame—as illustrated—as a separate element and to apply it on the metal upper layer 24, e.g. by sintering or some other measure familiar to a person skilled in the art. It is evident from the illustrations in the figures that a thickness of the frame 30 or of the recess 14 corresponds to a thickness or height of the component 12 (including the thickness of the connecting layer), as is known to a person skilled in the art. The connecting or joining layer from the sintering process, e.g. composed of silver, has a thickness portion of approximately 20 to 30 μm that is taken into account by a person skilled in the art in the design of the frame thickness.

The first embodiment is illustrated first of all in FIGS. 10 to 14. The carrier substrate 12 once again has a multilayer structure with the ceramic carrier 22 and the metal upper layer 24 assigned to the power electronic component 16, and with the component-remote metal lower layer 26. In order to form the recess 14 for the component 16, the frame 30 is applied on the metal upper layer 24 (as already mentioned e.g. by sintering indicated by the sintering layer 31 depicted).

According to the invention, the frame 30 comprises a section 32 projecting beyond the carrier substrate 12 (cf. the side view in FIG. 11 and the corresponding plan view in FIG. 12). The section 32 extends in particular in a direction beyond the outline contour of the actual carrier substrate 12. The section 32 extends beyond the carrier substrate 12 in the direction of the side at which the connection element 34 is to be formed. As is evident from the schematic lateral sectional view in FIG. 11, the edges of the ceramic carrier 22 also project somewhat beyond the edges of the metal layers 24, 26, which results from the implemented etching process as governed by production.

According to the invention, the section 32 projecting beyond the carrier substrate 12 is configured in bendable fashion. In particular, it can be bent in such a way that it extends over a height of the carrier substrate 12 as far as the metal lower layer 26 (cf. FIG. 14). Bending the projecting section 32 can be effected e.g. after sintering the frame 30 onto the metal upper layer 24 (sequence FIG. 11=>FIG. 14). Alternatively, the frame 30 with the projecting section 32 can be pre-bent and provided as a stamped and bent part, for example, and would then already be present in bent form before the sintering process, i.e. would be applied or sintered or the like in the bent state (an intermediate structure in accordance with FIG. 11 would not be present in this case).

In the bent state, the connection element 34 has substantially an S-shape in cross section. The projecting section 32 extends from the still horizontally oriented frame 30 vertically downward, i.e. in the component-remote direction, where it merges into a short contact section 32′ bent away horizontally.

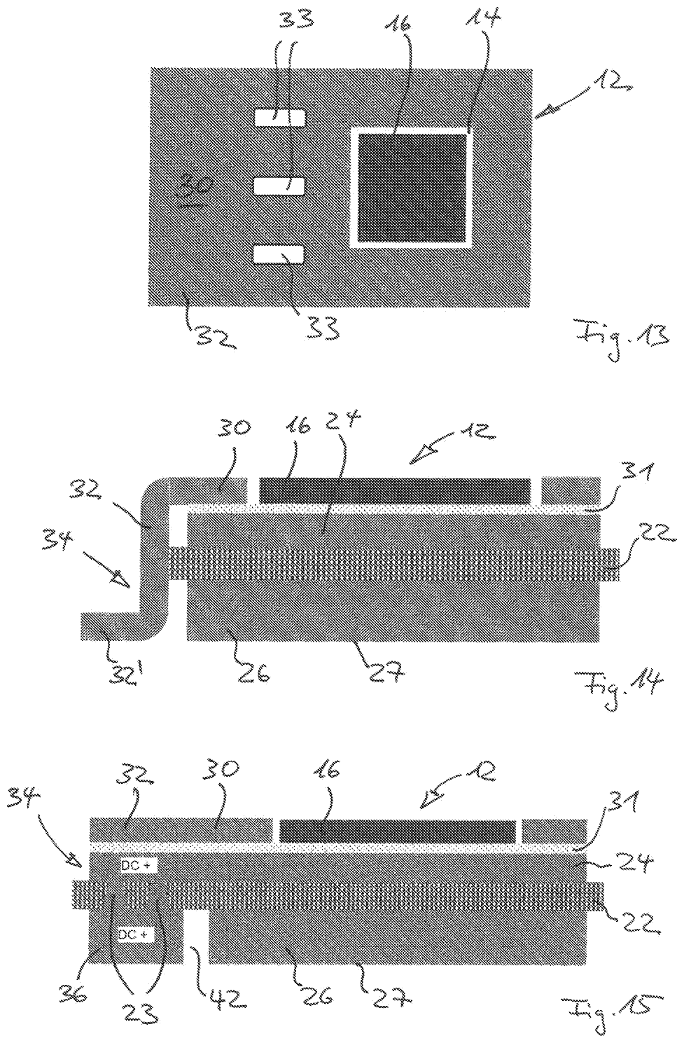

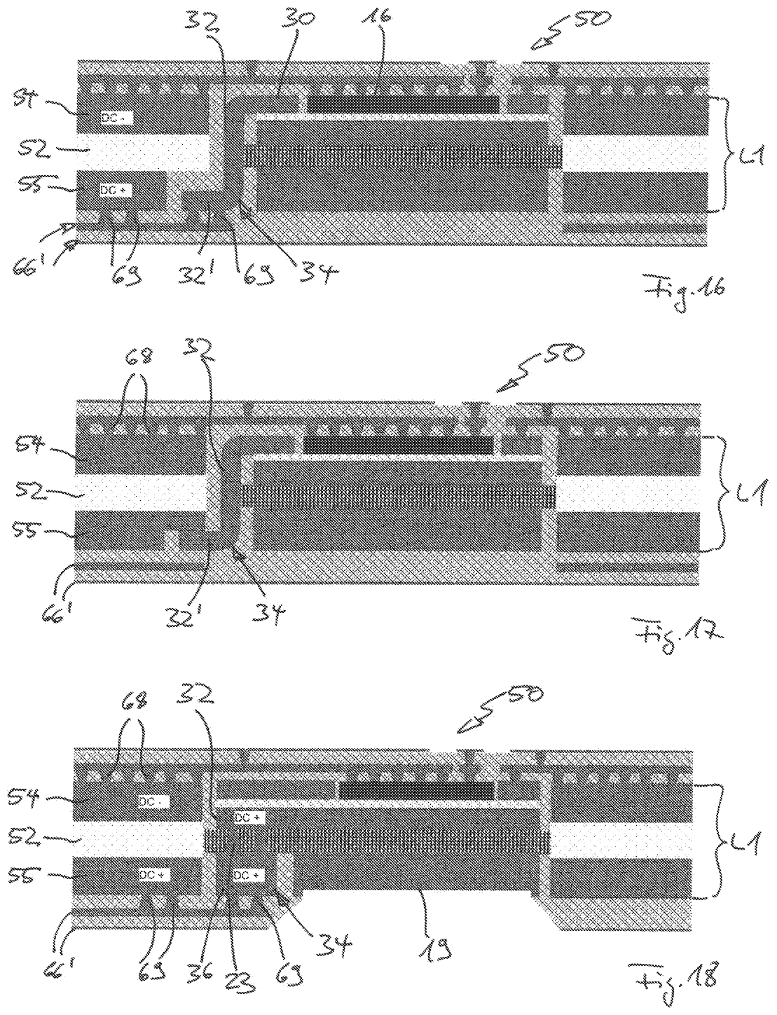

The carrier substrate 12 in FIG. 14 is subsequently introduced into a printed circuit board layer structure L1 of a printed circuit board 50 (cf. e.g. DE 10 2018 207 955 A1) and is pressed together with this layer structure, in a manner known per se. In order that a sufficient resin flow of the liquefied resin into all regions to be filled is ensured during pressing, one or more perforations 33 can be provided in the projecting section 32 of the frame 30. The perforations 33 are arranged in such a way that they enable the resin flow into all regions to be filled during pressing. By way of example, the perforations 33 can be arranged, as illustrated in FIG. 13, in such a way that they are located in an upper vertical bending region after the bending of the section 32. The embedded and pressed carrier substrate is illustrated e.g. in FIGS. 16 and 17. The perforations described can also be useful during a process of encapsulating with a mold compound, as will be described below, in order to ensure that the mold compound completely fills the cavity.

FIGS. 16 and 17 furthermore illustrate possible contact-connections of the connection element 34 in the printed circuit board 50.

In accordance with a first possibility illustrated in FIG. 16, the short horizontal contact section 32′ can be connected to the lower copper layer 55 by way of vias 69 (buried contact-connections or metallized blind holes (buried vias/blind vias)) by way of one of the conductor track layers 66′.

Alternatively, the short horizontal contact section 32′ can be directly connected to the lower copper layer 55, as illustrated in FIG. 17. This direct connecting can be effected by means of joining, for example. In manufacturing engineering, according to DIN 8580, “joining” is one (the fourth) of the six main manufacturing groups used to permanently connect (join) two or more solid bodies with a geometrically determined shape. Occasionally, so-called “shapeless material” is additionally used here as well, the shape of which is not defined. The individual process groups are defined in more specific detail in DIN 8593. The most important groups include, in particular, welding and also soldering and adhesive bonding. Possible joining processes that are appropriate in the present case include in particular sintering, soldering, diffusion soldering or the like; in particular, laser welding, silver sintering, ultrasonic welding and the like are appropriate as “joining”.

Therefore, according to the invention, the drain potential DC+ is connected from the metal upper layer 24 and the frame 30 to the lower copper layer 54 of the printed circuit board by way of the connection element 34, while the metal lower layer 26 of the carrier substrate is at floating ground.

The carrier substrate of the embodiment in FIG. 14 can have e.g. a total height of approximately 1 to 1.3 mm. The thickness of the component 16 is typically 50 to 350 μm and the depth of the recess 14 or the thickness of the frame 30 is correspondingly 50 to 350 μm. The thicknesses of the metal layers 24, 26 can typically lie between 50 and 800 μm and be e.g. around 300 μm, and the thickness of the ceramic carrier 22 can be e.g. 250 to 700 μm. The thickness of the sintering layer 31 is e.g. 20 to 40 μm. The horizontal length of the short horizontal contact section 32′ is e.g. 0.3 to 1.5 mm.

Referring to FIG. 15, a further embodiment of the connection element 34 will now be described.

In the case of the carrier substrate 12 of the embodiment in FIG. 15, in addition the metal upper layer 24 and the ceramic carrier 22 together with the frame 30 project beyond the outline contour of the carrier substrate 12. Through contacts 23 are provided in the projecting section of the ceramic carrier 22, the projecting section of the metal upper layer 24 being connected to a terminal layer 36 by way of said through contacts. The holes for the through contacts 23 can be produced by means of laser drilling, for example. The holes are then metallized, e.g. by means of a chemical (copper) process, and filled galvanically in a manner known per se to a person skilled in the art. In the case of the embodiment in FIG. 15, instead of the described process of applying the frame by sintering, analogously to the exemplary embodiments in FIGS. 7 to 10, it is also possible for a cavity/depression to be milled into the substrate 12 from above.

A method according to the invention for producing the embodiment variant mentioned last will be described with reference to the sectional illustrations in FIGS. 24 to 29.

Firstly, an initial carrier substrate 12′ is provided, having an insulating inner layer 22, with a metal lower layer 26 being formed on the underside of said inner layer and a metal upper layer 24 being formed on the top side of said inner layer. The insulating inner layer 22 can be in particular—as already explained above—a ceramic carrier. The metal layers can be in particular and typically copper.

In a subsequent step (FIG. 25), one or more holes 23′ are introduced through the metal lower layer 26 and the inner layer 22 as far as the metal upper layer 24. The holes 23′ are formed e.g. by means of a laser in a manner known per se (laser drilling).

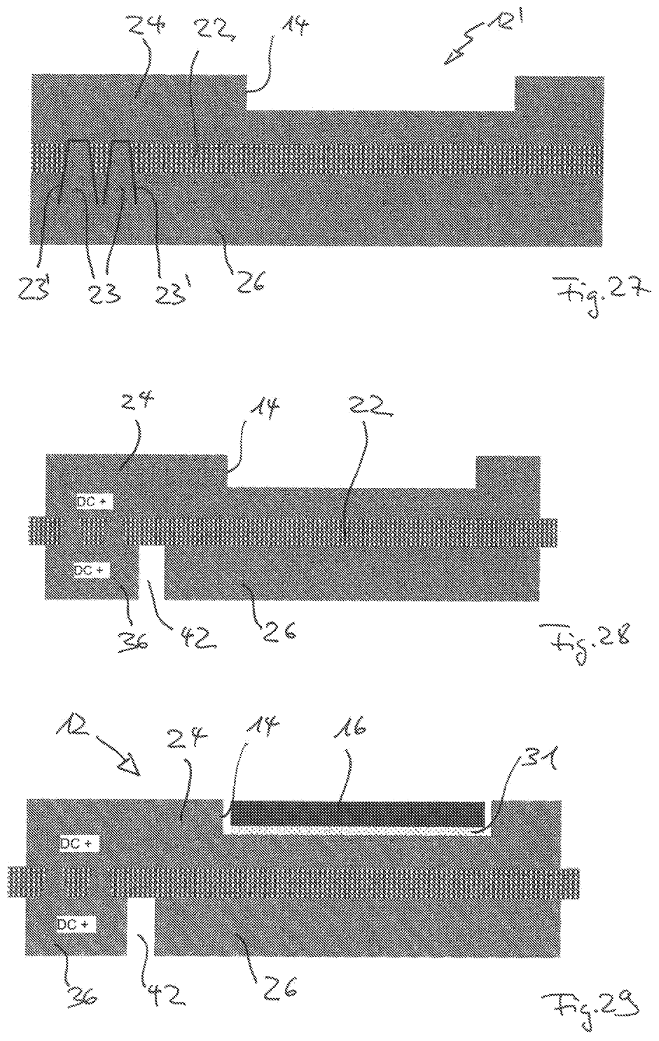

The holes 23′ introduced in this way are filled with electrically conductive material, in particular copper, likewise in a manner known per se, in order to form through contacts 23 from the metal lower layer 26 to the metal upper layer 24 (FIG. 26). For this purpose, e.g. firstly metal or copper is chemically applied (chemical Cu process), followed by e.g. galvanic application or plating of further copper. The thickness of the metal layers 24, 26 is also increased in the course of this.

As is likewise illustrated in FIG. 26, before the step of applying or plating further copper, photoresist material 40 can be applied to a defined region of the metal upper layer 24 in order to prevent copper from being deposited at this location, such that a recess 14 for later receiving a power electronic component 16 is formed at this location, i.e. the defined region.

FIG. 27 shows the metal-ceramic substrate 12′ after removal of the photoresist material 40 (e.g. by photoresist stripping) with the recess 14 formed in the metal upper layer 24 and with the through contacts 23. The earlier holes 23′ are still depicted using black lines merely as an aid to understanding. Applying the photoresist material is followed by the steps of exposing, developing and etching the structures, as known to a person skilled in the art.

The size and depth of the recess 14 are chosen such that the latter is suitable for receiving a power electronic component 16 including the sintering layer 31, in particular in such a way that, as described elsewhere, the depth or thickness of the recess 14 corresponds to the thickness of the power electronic component 16 plus the sintering layer 31 in order to attain a flush termination at the outer surface (FIG. 29).

Alternatively, as described above and illustrated in FIG. 15, the recess for receiving the component 16 can also be realized by applying a frame 30. As a further alternative, the recess can be realized by deep milling into the metal upper layer 24.

Stripping the photoresist material 40 can be followed by another patterning process, resulting in the removal of some copper all around, as a result of which, as is evident in FIG. 28 and has already been described above in association with FIG. 11, the edges of the inner layer 22 can project laterally somewhat beyond the edges of the metal layers 24, 26 (on the left and right in the illustration in FIG. 28). This projection facilitates the singulation of the modules from an array of modules; it does not arise if the module is singulated by a separating process, e.g. sawing, in which the separation is effected through the Cu-insulator-Cu layer composite without a preceding copper etching process. This projection has not been depicted in the plan view illustration in FIG. 12, for the sake of simplicity.

For the purpose of forming a potential-isolated terminal layer 36 in the manner according to the invention, a gap or a potential isolation 42 is furthermore introduced into the metal lower layer 26, e.g. by means of etching (FIG. 28), preferably at the same time as the patterning process described above. Said gap 42 separates a region of the metal lower layer 26 that is provided as a terminal layer 36 from said metal lower layer, with the result that two potential-isolated lower copper layers are present. According to the invention, the terminal layer 36 can be connected to a drain terminal of the power electronic component 16 at DC+ by way of the through contacts 23 and the metal upper layer 24, while the rest of the metal lower layer 26 is at floating ground.

FIG. 29, finally, shows the module 12 after being equipped with the component 16.

The carrier substrate 12 in FIG. 15, as above in association with the embodiment in FIG. 14, is embedded into a printed circuit board layer structure L1 and is pressed together and also electrically contact-connected therewith, e.g. by means of conductor tracks 66 and vias 68 (cf. FIG. 18). The electrical connection of the connection element 34 to the lower copper layer 35 of the printed circuit board 50 by way of the terminal layer 36 can be effected analogously to the contact-connection by way of vias 69 as described with reference to FIG. 16.

The printed circuit board configurations described with reference to FIGS. 16 to 18, by means of exposing an underside of the carrier substrate 12 (the exposing is indicated in the illustration in FIG. 18, but is intended, of course, also to apply analogously to the other configurations) according to the embodiments described with reference to FIGS. 3 to 10, can be connected to a cooling fluid flow body in order to achieve flow of cooling fluid around the carrier substrate in the manner according to the invention. It goes without saying that at the exposed outer surface 19 of the metal lower layer 26, cooling structures can also be formed or cooling structures e.g. in the form of a cooling structure body can be assigned or fitted, as has already been described above in association with FIGS. 6 and 8 to 10.

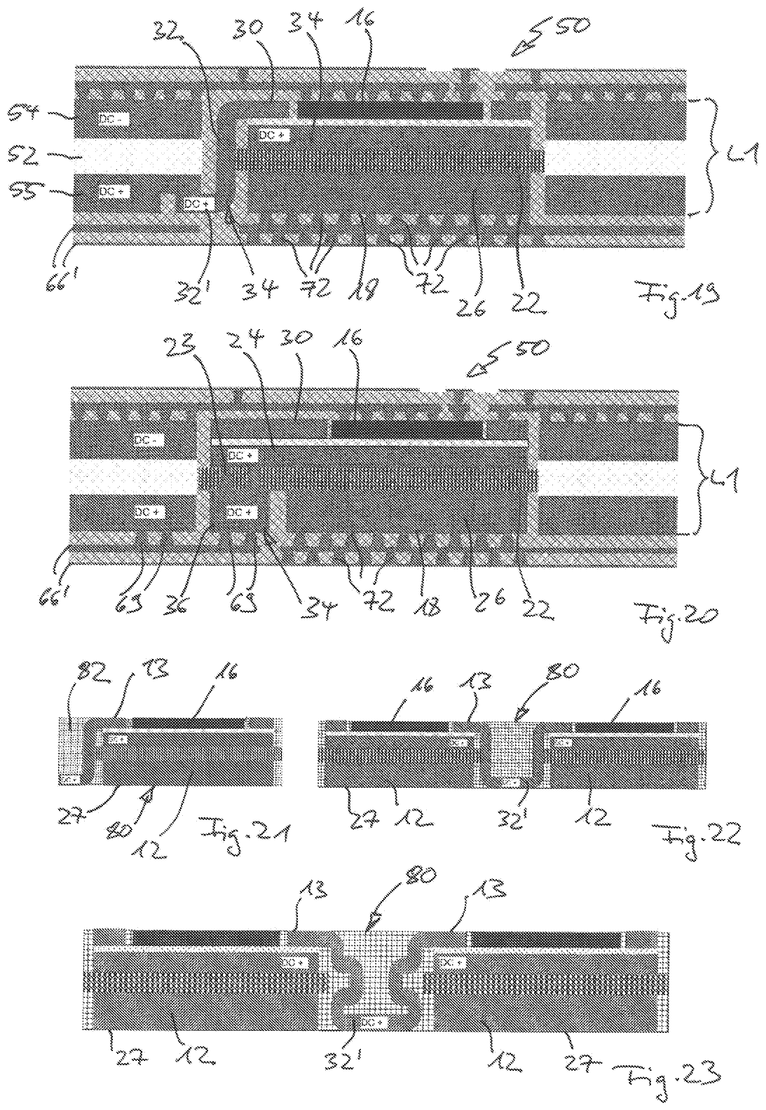

Alternatively—as is illustrated in FIGS. 19 and 20—further heat dissipation can be effected in a manner known per se by way of a plurality of vias 72 (buried vias/blind vias) from lower conductor track layers 66′, said vias being connected to the component-remote section 18. A structure of this type is connected in areal contact with an external heat sink (not illustrated), in a manner that is likewise known per se.

For the purposes of better handling and improved process control, the carrier substrate in FIG. 14 can be encapsulated in a molding or mold process (in particular transfer molding) using a molding compound to form a monolithic block 80 (cf. FIG. 21).

In this case, the outer surfaces 13, 27 of the top side and underside of the carrier substrate 12 can re-main free of molding compound (mold compound) 82, which can be achieved through the use of a so-called FAM process (FAM: foil or film assisted molding; foil or film assisted injection molding/transfer molding), thereby facilitating the later contact-connection (vias 68, 69, 72). The FAM method is a transfer molding method which is known per se to a person skilled in the art and uses one or two foils in the mold, which are sucked onto the inner surface (by application of a vacuum or sufficient reduced pressure) before the product to be encapsulated is inserted, followed by the actual transfer molding.

Typical materials for encapsulation (molding compounds) are likewise known per se to a person skilled in the art and originate from the groups of thermoplastics or thermosetting plastics, in particular from the group of formaldehydes, more particularly phenoplasts or melamine resins, or reaction resins, more particularly polyesters or epoxy resins.

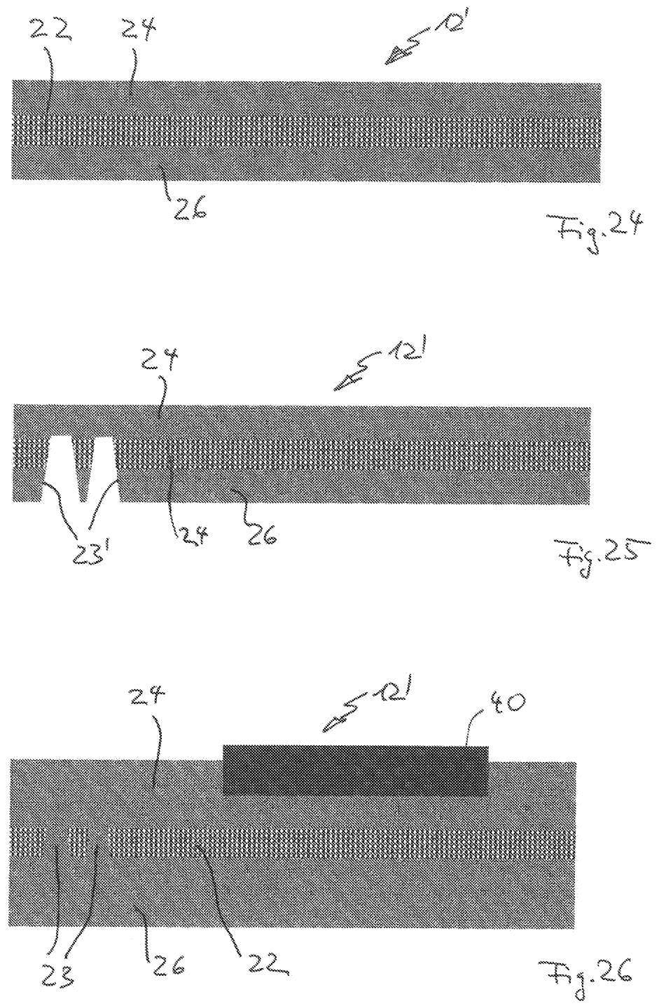

FIG. 22 analogously shows a double cell 80, with two carrier substrates 12 being potted into a block, wherein the two carrier substrates are arranged with their horizontal contact sections 32′ facing one another in such a way that the contact sections are connected to one another and the drain potentials of the two components 16 are thus interconnected. As is illustrated in FIG. 23, the connection elements 34 can be provided with an additional bend for forming a flexible region for mechanical tolerance compensation during the mold process. An additional bend of this type can result in a double S-shape, for example, as illustrated. This design achieved in this way can be embedded into the printed circuit board if cells are connected in parallel, as illustrated. However, it can also be changed to a design analogous to that illustrated in FIG. 21 in a subsequent process (not illustrated), e.g. by means of sawing. The double cell illustrated can analogously be produced as a multiple cell (two to any desired number) and, after the mold process, can be singulated into any desired number of cells connected in parallel (2, 3, 5, 8, etc.).

1-18. (canceled)

19. A power electronic module for integration into a printed circuit board, comprising:
a carrier substrate and a power electronic component fitted into a recess in the carrier substrate;
wherein the carrier substrate is formed as a heat sink or heat dissipation body composed of one or more materials of high thermal conductivity at least in a region below the power electronic component.

20. The power electronic module according to claim 19, wherein a component-remote section of the carrier substrate is configured for direct contact with cooling fluid and has a coating compatible with the cooling fluid.

21. The power electronic module according to claim 19, wherein a component-remote section of the carrier substrate has surface-enlarging or heat-dissipating structures or cooling-fluid-guiding structures, or wherein a component-remote section of the carrier substrate is assigned surface-enlarging or heat-dissipating structures or cooling-fluid-guiding structures.

22. The power electronic module according to claim 19, wherein the carrier substrate comprises a multilayer structure with an insulating inner layer, a metal upper layer assigned to the power electronic component, and a component-remote metal lower layer.

23. The power electronic module according to claim 22, which has a connection element extending outside the multilayer structure substantially perpendicularly to the multilayer structure for electrical connection of the power electronic component, the connection element extending over a height of the carrier substrate as far as the metal lower layer and terminates substantially flush with an outer surface of the metal lower layer.

24. The power electronic module according to claim 22, wherein a frame for receiving the power electronic component is provided on or in the metal upper layer, the frame including an electrically conductive material and a section projecting beyond the carrier substrate for forming an electrical connection element for the power electronic component, the frame including a section projecting beyond the carrier substrate.

25. The power electronic module according to claim 24, wherein the section projecting beyond the carrier substrate is bent in such a way that it extends over a height of the carrier substrate as far as the metal lower layer or in such a manner that it terminates substantially flush with an outer surface of the metal lower layer.

26. The power electronic module according to claim 25, wherein the bent section has substantially an S-shape or a double S-shape in cross section.

27. The power electronic module according to claim 24, wherein the metal upper layer and the ceramic carrier together with the frame project beyond the carrier substrate and a conduction section extending through the ceramic carrier is provided for forming the electrical connection element.

28. The power electronic module according to claim 21, wherein the surface-enlarging or heat-dissipating structures or cooling-fluid-guiding structures includes channels, cooling fins, cooling pins, studs or contact-connections.

29. The power electronic module according to claim 22, wherein the multilayer structure includes a metal-ceramic substrate with a ceramic carrier as the insulating inner layer.

30. A power electronic module for integration into a printed circuit board, comprising:
a carrier substrate formed as a heat sink or heat dissipation body composed of one or more materials of high thermal conductivity at least in a region below the power electronic component; and
a power electronic component introduced into a recess in the carrier substrate;
wherein the carrier substrate comprises a multilayer structure with an insulating inner layer, a metal upper layer assigned to the power electronic component, and a component-remote metal lower layer;
wherein the module has a connection element extending outside the multilayer structure substantially perpendicularly to the multilayer structure for electrical connection of the power electronic component, the connection element extending over a height of the carrier substrate) as far as the metal lower layer and terminates substantially flush with an outer surface of the metal lower layer.

31. The power electronic module according to claim 30, wherein a frame for receiving the power electronic component is provided on or in the metal upper layer, the frame including an electrically conductive material and a section projecting beyond the carrier substrate for forming an electrical connection element for the power electronic component, the frame including a section projecting beyond the carrier substrate.

32. The power electronic module according to claim 30, wherein the section projecting beyond the carrier substrate is bent in such a way that it extends over a height of the carrier substrate as far as the metal lower layer or in such a manner that it terminates substantially flush with an outer surface of the metal lower layer.

33. The power electronic module according to claim 32, wherein the bent section has substantially an S-shape or a double S-shape in cross section.

34. The power electronic module according to claim 31, wherein the metal upper layer and the ceramic carrier together with the frame project beyond the carrier substrate and a conduction section extending through the ceramic carrier is provided for forming the electrical connection element.

35. The power electronic module according to claim 34, wherein the conduction section is formed by means of at least one through contact through the ceramic carrier.

36. The power electronic module according to claim 30, wherein the power electronic module is integrated into a printed circuit board to form a power electronic module block, wherein the module is encapsulated by means of transfer molding with a mold compound to form a monolithic block in such a way that an upper outer surface of the carrier substrate and an outer surface of the metal lower layer are suitably exposed for contact-connection.

37. The power electronic module according to claim 30, wherein the power electronic module block is inserted into the printed circuit board layer structure and pressed together.

38. A printed circuit board, comprising:
a printed circuit board layer structure;
a power electronic module comprising inserted into the printed circuit board layer structure and pressed together; and
the power electronic module comprising a carrier substrate and a power electronic component fitted into a recess in the carrier substrate, the carrier substrate being formed as a heat sink or heat dissipation body composed of one or more materials of high thermal conductivity at least in a region below the power electronic component.

39. The printed circuit board according to claim 38, wherein a cooling fluid flow body is arranged at an underside of the printed circuit board in a manner assigned to a component-remote section of the carrier substrate.

40. The printed circuit board according to claim 39, wherein a component-remote section of the carrier substrate is exposed by deep milling in order to allow cooling fluid to be applied, wherein the cooling fluid flow body has a cooling fluid guide structure designed to feed cooling fluid to the exposed component-remote section for direct flow around.

41. The printed circuit board according to claim 40, wherein the cooling fluid flow body has cooling channels at a surface facing the exposed component-remote section.

42. The printed circuit board according to claim 38, wherein the carrier substrate comprises a multilayer structure with an insulating inner layer, a metal upper layer assigned to the power electronic component, and a component-remote metal lower layer.

43. The printed circuit board according to claim 38, wherein:
a connection element extends outside the multilayer structure substantially perpendicularly to the multilayer structure for electrical connection of the power electronic component;
the connection element extends over a height of the carrier substrate as far as the metal lower layer and terminates substantially flush with an outer surface of the metal lower layer.

44. The printed circuit board according to claim 43, wherein the electronic module is inserted into the printed circuit board layer structure and pressed together, wherein the connection element is electrically connected by joining or by means of inner layer connections, to a conductive layer of the printed circuit board layer structure that terminates substantially flush with the metal lower layer.

45. A method for producing a power electronic module comprising a carrier substrate and a power electronic component fitted into a recess in the carrier substrate, the carrier substrate comprising a multilayer structure with an insulating inner layer, a metal upper layer assigned to the power electronic component, and a component-remote metal lower layer, the method comprising the following steps:
providing an initial carrier substrate comprising an insulating inner layer, a metal lower layer formed thereunder, and a metal upper layer formed thereon;
forming one or more holes through the metal lower layer and the insulating inner layer;
filling the holes with electrically conductive material for the purpose of forming through contacts;
etching the metal lower layer for forming a potential-isolated terminal layer.

46. The method according to claim 45, and further comprising the step of chemical metal deposition in the holes before the filling step.

47. The method according to claim 45, and further comprising the step of applying further metal to the metal upper layer or the metal lower layer.

48. The method according to claim 47, wherein before the step of applying further metal, a defined region of the metal upper layer is covered with photoresist material in order to form a recess for receiving a power electronic component by way of applying metal, followed by the step of removing the photoresist material.

49. The method according to claim 45, and further comprising the step of applying a frame to the metal upper layer with a cutout for receiving a power electronic component by means of sintering.

50. The method according to claim 48, and further comprising the step of inserting a power electronic component into the recess in the metal upper layer or the cutout in the frame.

51. The method according to claim 45, and further comprising the step of encapsulating the power electronic module by means of injection molding or transfer molding to form a monolithic block for forming a power electronic module block suitable for integration into a printed circuit board.
